(19) United States
(12) Patent Application Publication
(10) Pub. No.: US 2003/0001589 A1
(43) Pub. Date: Jan. 2, 2003

(54) Redundant electric fuses

(75) Inventors: Tsiu Chiu Chan, Carrollton, TX (US); Elmer H. Guritz, Flower Mound, TX (US); Michael J. Callahan JR., Austin, TX (US)

Correspondence Address: Lisa K. Jorgenson, Esq., STMicroelectronics, Inc., 1310 Electronics Drive, Carrollton, TX, 75006, US

(73) Assignee: STMicroelectronics, Inc., Carrollton, TX (US)

(21) Appl. No.: 10/135,880

(22) Filed: Apr. 29, 2002

Related U.S. Application Data
(63) Continuation-in-part of application No. 09/467,617, filed on Dec. 20, 1999, now Pat. No. 6,381,115.

(51) Int. Cl. G01R 31/02

(52) U.S. Cl. 324/550

(57) ABSTRACT

A fuse-redundancy circuit for use in an integrated circuit and method for operating the same. The fuse-redundancy circuit comprises at least two fuses, at least two fuse-control devices, and a status-checking circuit. Each one of the at least two fuse-control devices is operable to control an electric current flowing through a corresponding one of the at least two fuses. The status-checking circuit operable to generate a status signal having (i) a first state when at least one of the at least two fuses is blown, and (ii) a second state otherwise.

This application is a continuation-in-part (CIP) of U.S. patent application Ser. No. 09/467,617, filed on Dec. 20, 1999.

### CROSS-REFERENCE TO RELATED APPLICATIONS

The present invention is related to that disclosed in U.S. patent application Ser. No. 09/467,617, filed on Dec. 20, 1999, entitled “REDUNDANT ELECTRICAL FUSES”. U.S. patent application Ser. No. 09/467,617 is commonly assigned to the assignee of the present invention. The disclosure of the related patent application is hereby incorporated by reference for all purposes as if fully set forth herein.

### TECHNICAL FIELD OF THE INVENTION

The present invention relates to fuses in integrated circuits and, in particular, to multiple electric fuses for redundancy.

### BACKGROUND OF THE INVENTION

Fuses are devices extensively used in integrated circuits to provide a way to program, repair, or modify the operation of, an integrated circuit after the circuit has been manufactured. Typical applications for semiconductor fuses include programmability of memory (PROM, EPROM) and disablement/enablement of certain circuitry for redundancy purposes (memories), and the like.

The two main types of fuses in common use by the semiconductor industry are electric fuses and optical fuses. Optical fuses are blown (or open-circuited) using radiation (such as laser) while electric fuses are blown by an electric current flowing through the electric fuse. In many applications, electric fuses are preferred over optical fuses due to the complexity and time needed to blow optical fuses using radiation.

One problem that exists with electric fuses is that sometimes after an electric fuse is blown, the fuses can reform upon cooling or sometime thereafter. While additional and complex testing may detect such a defect, it is generally desirable to blow the fuse(s) and perform no additional testing (in most cases, the testing has already been performed prior to the blowing of the fuses). In addition, even though duplication of the step of blowing the fuse may sometimes bring success in re-blowing a fuse that has reformed immediately, there is still a substantial possibility that the fuse may reform again after packaging of the die or during use in the field. If this occurs, the integrated circuit will be (or become) defective and cannot be repaired, thereby reducing the yield or affecting the IC during customer operation.

Accordingly, there exists a need to increase the yield of integrated circuits (and decrease the likelihood of failure in the field) that utilize electric fuses therein by reducing the likelihood that a reformed electric fuse (reformed after blowing) will cause a fatal defect.

### SUMMARY OF THE INVENTION

To address the above-discussed deficiencies of the prior art, it is a primary object of the present invention to provide a fuse-redundancy circuit for use in an integrated circuit and method for operating the same.

According to one embodiment, the fuse-redundancy circuit comprises at least two fuses, at least two fuse-control devices, and a status-checking circuit. Each one of the at least two fuse-control devices is operable to control an electric current flowing through a corresponding one of the at least two fuses. The status-checking circuit operable to generate a status signal having (i) a first state when at least one of the at least two fuses is blown, and (ii) a second state otherwise.

In a related embodiment, the at least two fuses are coupled in series. According to one exemplary implementation of this embodiment, the fuse-redundancy circuit includes a first fuse of conductive material that has a first side coupled to a first node and a second side coupled to a second node, along with a first control device having a first terminal, a second terminal, and a control terminal, such that the first terminal is coupled to the first node, the second terminal is coupled to a first reference voltage, and the control terminal is coupled to a first fuse control signal whereby the first control device is operable, in response to the first fuse control signal, to cause an electric current to flow through the first fuse sufficient to blow open the first fuse. The fuse-redundancy circuit also includes a second fuse of conductive material and having a first side coupled to the second node and a second side coupled to a second reference voltage, and a second control device having a first terminal, a second terminal, and a control terminal, such that the first terminal is coupled to the second node, the second terminal is coupled to a third reference voltage and the control terminal is coupled to a second fuse control signal whereby the second control device is operable, in response to the second fuse control signal, to cause an electric current to flow through the second fuse sufficient to blow open the second fuse. This embodiment is fully disclosed in U.S. patent application Ser. No. 09/467,617, entitled “REDUNDANT ELECTRICAL FUSES”, which is assigned to the assignee of the present invention, this disclosure of this related patent application is incorporated herein by reference for all purposes as if fully set forth herein.

In an alternate related embodiment of the fuse-redundancy circuit, the at least two fuses are coupled in parallel.

In another related embodiment of the fuse-redundancy circuit, the status-checking circuit is includes circuit logic, such as one of an AND gate, a NAND gate, an OR gate and a NOR gate.

In another related embodiment of the fuse-redundancy circuit, one of the at least two fuse-control devices comprises one of n-channel transistor, a p-channel transistor and a resistor.

In another related embodiment of the fuse-redundancy circuit, the at least two fuse-control devices control the electric current flowing through the corresponding fuses in response to a corresponding one of a plurality of fuse control signals.

According to another embodiment of the present invention, a method of blowing a fuse-redundancy circuit for use in an integrated circuit (IC) is introduced. The fuse-redundancy circuit includes at least two fuses and at least two fuse-control devices, each one of the at least two fuse-control devices is operable to control an electric current flowing through a corresponding one of the at least two fuses. The method comprising the steps of (i) controlling current flowing through fuse-redundancy circuit, the current having a magnitude sufficient to blow each of the at least two fuses, and (ii) generating a status signal having a first state when at least one of the at least two fuses is blown, and a second state otherwise.

According to yet another embodiment of the present invention, a fuse-redundancy circuit for use in an integrated circuit (IC) comprises a first fuse and a second fuse, a first fuse-control device, a second fuse-control device, and a status-checking circuit. The first fuse-control device is operable to control a first current flowing through the first fuse, and the second fuse-control device is operable to control a second current flowing through the second fuse. The status-checking circuit is operable to generate a status signal having (i) a first state when at least one of the first fuse and the second fuse is blown, and (ii) a second state otherwise.

In a related embodiment, the at least two fuses may suitably be coupled in series, whereas in an alternated related embodiment, the at least two fuses may suitably be coupled in parallel.

In another related embodiment, at least one of the first current and the second current flows respectively through the first fuse and the second fuse in response to a corresponding one of a plurality of fuse control signals.

The foregoing has outlined rather broadly the features and technical advantages of the present invention so that those skilled in the art may better understand the detailed description of the invention that follows. Additional features and advantages of the invention will be described hereinafter that form the subject of the claims of the invention. Those skilled in the art should appreciate that they may readily use the conception and the specific embodiment disclosed as a basis for modifying or designing other structures for carrying out the same purposes of the present invention. Those skilled in the art should also realize that such equivalent constructions do not depart from the spirit and scope of the invention in its broadest form.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. In particular, a controller may comprise a data processor and an associated memory that stores instructions that may be executed by the data processor. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present invention, and the advantages thereof, reference is now made to the following descriptions taken in conjunction with the accompanying drawings, wherein like numbers designate like objects, and in which:

FIG. 1 is a schematic diagram illustrating redundant fuses according to an exemplary embodiment of the present invention;

FIG. 2 is a schematic diagram illustrating the redundant fuses of FIG. 1 used in conjunction with a latch circuit according to a first embodiment of the present invention;

FIG. 3 illustrates redundant fuses used in conjunction with a fuse status circuit according to a second embodiment of the present invention;

FIG. 4 illustrates redundant fuses used in conjunction with a fuse status circuit according to a fourth embodiment of the present invention; and

FIG. 5 illustrates redundant fuses used in conjunction with a fuse status circuit according to a fifth embodiment of the present invention.

### DETAILED DESCRIPTION OF THE INVENTION

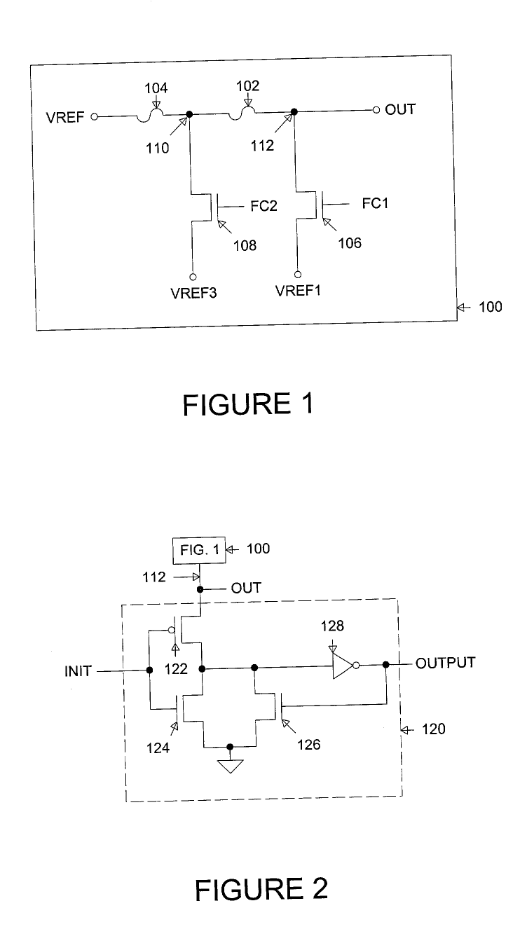

FIGS. 1 through 5, discussed herein, and the various embodiments used to describe the principles of the present invention in this patent document are by way of illustration only and should not be construed in any way to limit the scope of the invention. Those skilled in the art will understand that the principles of the present invention may be implemented in any suitably arranged integrated circuit.

Now referring to FIG. 1, there is shown a schematic diagram a fuse circuit 100 in accordance with the present invention. The fuse circuit 100 includes a fuse 102, a fuse 104, a fuse control device 106 and a fuse control device 108, as shown in FIG. 1.

One end of the fuse 102 and one terminal of the fuse control device 106 are coupled to a node 112, while the other end of the fuse 102, one end of the fuse 104 and one terminal of the fuse control device 108 are coupled to a node 110. Another terminal of the fuse control device 106 is coupled to a first voltage reference VREF1 with the control terminal coupled to a fuse control signal FC1. Additionally, the other endo f the fuse 104 is coupled to a second voltage reference VREF2. Another terminal of the fuse control device 108 is coupled to a third voltage reference VREF3 with the control terminal coupled to a fuse control signal FC2.

The fuses 102, 104 are electric fuses of the type that are blown when a predetermined amount of current flows through the fuse. The fuses 102, 104 are constructed of a conductive material, such as polysilicon. In a preferred embodiment, the fuses 102, 104 are constructed of doped polysilicon that is unsalicided. Additionally, the fuses 102, 104 each have a resistance and a power dissipation per unit cross section area (or current density) (and assuming height (or thickness) is constant) associated therewith depending on geometry and composition of the fuse. In a preferred embodiment, the power dissipation per unit cross section area of the fuse 102 is greater than the power dissipation per unit cross section area of the fuse 104, and preferably about two times or more greater. As will be appreciated, and assuming a substantially same composition and same thickness of conductive material for both fuses 102, 104, in order to achieve a larger power dissipation per unit cross section area for the fuse 102, the fuse 102 is shaped such that it is more narrow (and with the same length) than the fuse 104. Thus, if the thickness and length are the same for the two fuses, then a smaller width provides a greater power dissipation per unit cross section area. It will be understood that one of ordinary skill in the rt can easily select a composition and shape (length, height, and width) of th fuses to achieve the desired result.

In the one embodiment, the fuse control devices 106, 108 and MOS transistors, and in a preferred embodiment, the devices 106, 108 are n-channel devices and the second voltage reference (VREF2) is Vdd (or power) while the first and third reference voltages (VREF1, VREF3) are both ground. As will be appreciated, the first and third reference voltages do not have to be at the same voltage reference, provided the voltage values are sufficient to provide a current flowing between the second reference voltage (VREF2) and the first voltage reference (VREF1) (flowing through the fuses 102 and 104) when the fuse control device 106 is turned ‘on’, and to provide a current flowing between the second reference voltage (VREF2) and the third voltage reference (VREF3) (flowing through the fuse 104) when the fuse control device 104 is turned ‘on’. It will be understood that the fuse control devices 106, 108 are relatively large transistors having a substantial W/L ratio adequate to allow a sufficient current to flow through the fuses in order to blow the fuses. It will also be understood that the fuse control devices 106, 108 may alternatively be p-channel MOS transistors.

The basic operation of blowing the fuses 102, 104 of the fuse circuit 100 will now be described (assuming VREF2 is power and VREF1 and VREF3 are both ground). The fuse control signal FC1 is activated thereby turning on the fuse control device 106 and generating a current flowing through both the fuses 102, 104 sufficient to blow (open circuit) the fuse 102. Due to the higher power dissipation per unit cross section area of the fuse 102, the fuse 102 will incur higher power dissipation (get hotter) than the fuse 104 and will blow first. As will be appreciated, the period of time needed for blowing use 102 will depend mainly upon the composition and geometry of the fuse 102, the voltage differential between VREF2 and VREF1, and the size of the fuse control device 106.

After fuse 102 is blown, the fuse control signal FC2 is activated thereby turning on the fuse control device 108 and generating a current flowing through the fuse 104 sufficient to blow the fuse 104 (open circuit). As will be appreciated, the period of time needed for blowing fuse 104 will depend mainly upon the composition and geometry of the fuse 104, the voltage differential between VREF2 and VREF3, and the size of the fuse control device 108.

Having a redundant fuse system in accordance with the present invention increases the yield of integrated circuits that utilize fuses to repair or modify circuitry (e.g., redundant rows or columns in memory). It will be understood that if a fuse itself is inoperable or defective due to failure to blow (i.e., reformed after blowing), then an integrated circuit that would normally be operational if the fuse operated as desired will be defective. The present invention decreases the probability that a defective fuse will cause a fatal defect in an integrated circuit.

Now referring to FIG. 2, there is shown a schematic diagram illustrating the fuse circuit 100 of FIG. 1 in conjunction with a fuse latch circuit 120. The fuse latch circuit 120 generates an output signal (OUTPUT) having a first state when one or both of the fuses 102, 104 are blown (open-circuited) and having a second state when none of the fuses 102, 104 are blown. The fuse latch circuit 120 shown is only one embodiment of a fuse latch circuit that may be utilized with the fuse circuit 100. It will be understood that many configurations of latch circuits may be utilized as long as the desired results are achieved.

In the embodiment shown in FIG. 2, the fuse latch circuit 120 includes a p-channel MOS transistor 122 coupled to the node (OUT) 112 of the fuse circuit 100, two n-channel MOS transistors, and an inverter 128, all configured as shown. An initialize signal (INIT) is coupled to the gate (control) terminals of the transistors 122, 124. The INIT signal is a pulsed signal that latches in the state of the fuse circuit 100 (state one—at least one fuse blown; state two—b 0 fuses blown). In the present embodiment shown, the INIT signal is normally active high, and after the pulse goes low, the state of the fuse circuit 100 is latched, with a logic zero output when none of the fuses is blown and a logic one when at least one of the fuses is blown. Described in a different way, the node 112 is coupled to the voltage reference (VREF2) (see FIG. 1) when none of the plurality of fuses are blown and decoupled from the voltage reference (VREF2) when at least one of the plurality of fuses is blown.

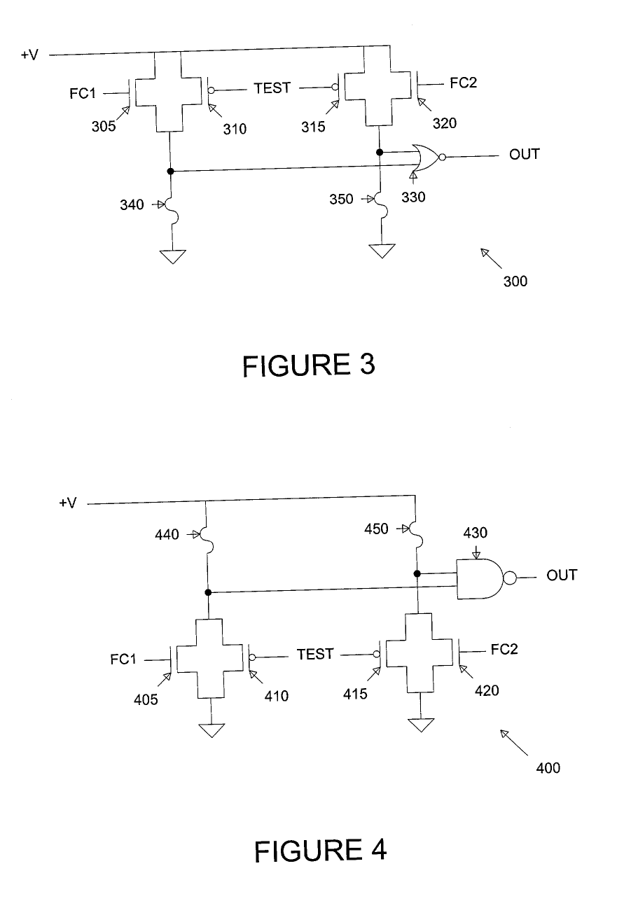

FIG. 3 illustrates redundant fuses used in conjunction with fuse status circuit 300 according to a second embodiment of the present invention. Fuse status circuit 300 comprises N-channel transistor 305, optional P-channel transistors 310 and 315, N-channel transistor 320, NOR gate 330, fuse 340 and fuse 350. When the fuse control signal, FC1, on the gate of N-channel transistor 305 is set high, N-channel transistor 305 drives a large amount of current through fuse 340, causing fuse 340 to blow (i.e., become an open-circuit). When the fuse control signal, FC2, on the gate of N-channel transistor 320 is set high, N-channel transistor 320 drives a large amount of current through fuse 350, causing fuse 350 to blow (i.e., become an open-circuit).

NOR gate 330 verifies the state of fuses 340 and 350. Depending on whether the OUT signal is an active high or an active low signal, NOR gate 330 may also be implemented as an OR gate. If fuse 340 is not blown, fuse 340 shorts a first input (input A) of NOR/OR gate 330 to ground (i.e., Logic 0). Otherwise, input A appears to be a Logic 1. Likewise, if fuse 350 is not blown, fuse 350 shorts a second input (input B) of NOR/OR gate 330 to ground (i.e., Logic 0). Otherwise, input B appears to be a Logic 1.

The truth table of NOR/OR gate 330 is shown in TABLE 1:

TABLE 1

| A | B | NOR | OR |
|---|---|---|---|
| 0 | 0 | 1 | 0 |
| 0 | 1 | 0 | 1 |
| 1 | 0 | 0 | 1 |
| 1 | 1 | 0 | 1 |

If OUT is an active low signal, then a NOR gate is implemented and NOR gate 330 goes low (i.e., Logic 0) to indicate that one or both of fuses 340 and 350 has been blown. If the output of NOR gate 330 is Logic 1, then neither of fuses 340 and 350 has been blown.

If OUT is an active high signal, then an OR gate is implemented and OR gate 330 goes high (i.e., Logic 1) to indicate that one or both of fuses 340 and 350 has been blown. If the output of OR gate 330 is Logic 0, then neither of fuses 340 and 350 has been blown.

After fuses 340 and 350 are blown, the signal TEST may be toggled between Logic 0 and Logic 1 in order to turn P-channel transistors 310 and 315 ON and OFF. This causes the OUT signal to switch between Logic 0 and Logic 1.

FIG. 4 illustrates redundant fuses used in conjunction with fuse status circuit 400 according to a fourth embodiment of the present invention. Fuse status circuit 400 comprises N-channel transistor 405, optional P-channel transistors 410 and 415, N-channel transistor 420, NAND gate 430, fuse 440 and fuse 450. When the fuse control signal, FC1, on the gate of N-channel transistor 405 is set high, N-channel transistor 405 drives a large amount of current through fuse 440, causing fuse 440 to blow (i.e., become an open-circuit). When the gate of N-channel transistor 420 is set high, N-channel transistor 420 drives a large amount of current through fuse 450, causing fuse 450 to blow (i.e., become an open-circuit).

NAND gate 430 verifies the state of fuses 440 and 450. Depending on whether the OUT signal is an active high or an active low signal, NAND gate 430 may also be implemented as an AND gate. If fuse 440 is not blown, fuse 440 shorts a first input (input A) of NAND/AND gate 430 to the positive power supply, +V (i.e., Logic 1). Otherwise, input A appears to be a Logic 0. Likewise, if fuse 450 is not blown, fuse 450 shorts a second input (input B) of NAND/AND gate 430 to the positive power supply, +V (i.e., Logic 1). Otherwise, input B appears to be a Logic 0.

The truth table of NAND/AND gate 430 is shown in TABLE 2:

TABLE 2

| A | B | NAND | AND |
|---|---|---|---|
| 0 | 0 | 1 | 0 |
| 0 | 1 | 1 | 0 |
| 1 | 0 | 1 | 0 |
| 1 | 1 | 0 | 1 |

If OUT is an active low signal, then an AND gate is implemented and AND gate 430 goes low (i.e., Logic 0) to indicate that one or both of fuses 440 and 450 has not been blown. If the output of AND gate 430 is Logic 1, then neither of fuses 440 and 450 has been blown.

If OUT is an active high signal, then a NAND gate is implemented and NAND gate 430 goes high (i.e., Logic 1) to indicate that one or both of fuses 440 and 450 has been blown. If the output of NAND gate 430 is Logic 0, then neither of fuses 440 and 450 has been blown.

After fuses 440 and 450 are blown, the signal TEST may be toggled between Logic 0 and Logic 1 in order to turn P-channel transistors 410 and 415 ON and OFF. This causes the OUT signal to switch between Logic 0 and Logic 1.

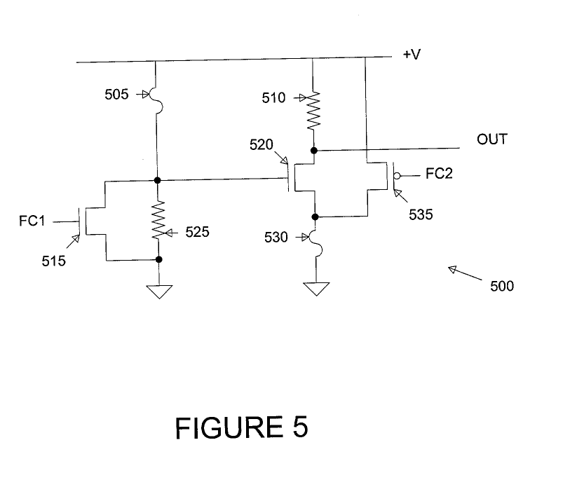

FIG. 5 illustrates redundant fuses used in conjunction with fuse status circuit 500 according to a fifth embodiment of the present invention. Fuse status circuit 500 comprises fuse 505, resistor 510, N-channel transistor 515, N-channel transistor 520, resistor 525, fuse 530, and P-channel transistor 535. When the fuse control signal, FC1, on the gate of N-channel transistor 515 is set high, N-channel transistor 515 drives a large amount of current through fuse 5050, causing fuse 505 to blow (i.e., become an open-circuit). When the gate of P-channel transistor 535 is set low, P-channel transistor 535 drives a large amount of current through fuse 530, causing fuse 530 to blow (i.e., become an open-circuit).

N-channel transistor 520 and resistors 510 and 525 verify the state of fuses 505 and 510. After FC1 and FC2 are disabled (i.e., N-channel transistor 515 and P-channel transistor 535 are OFF), if fuse 505 is blown, the gate of N-channel transistor 520 is pulled down to ground by resistor 525 and N-channel transistor 520 is turned OFF (regardless of the condition of fuse 530). Since N-channel transistor 520 is OFF, no current flows through N-channel transistor 520 and resistor 510 pulls the OUT signal up to the positive supply rail voltage, V+. If fuse 530 is blown, the source of N-channel transistor 520 is open-circuited and no current can flow through N-channel transistor 520 (regardless of the condition of fuse 505). Since no current flows through N-channel transistor 520, resistor 510 pulls the OUT signal up to the positive supply rail voltage, V+. Thus, if either of fuses 505 and 530 are blown, the OUT signal is high (i.e., Logic 1).

However, after FC1 and FC2 are disabled (i.e., N-channel transistor 515 and P-channel transistor 535 are OFF), if neither fuse 505 nor fuse 530 is blown, then the gate of N-channel transistor 520 is pulled up to the positive supply rail voltage, V+, and the source of N-channel transistor 520 is shorted to ground. In this state, N-channel transistor 520 is ON and current flow through N-channel transistor 520. This causes a voltage drop across resistor 510 and the OUT signal is pulled down to ground. Thus, if neither of fuses 505 and 530 is blown (i.e., both are shorts), the OUT signal is low (i.e., Logic 0).

Although the present invention has been described in detail, those skilled in the art should understand that they can make various changes, substitutions and alterations herein without departing from the spirit and scope of the invention in its broadest form.

What is claimed is:

1. For use in an integrated circuit (IC), a fuse-redundancy circuit comprising:
at least two fuses;
at least two fuse-control devices, each one of said at least two fuse-control devices operable to control an electric current flowing through a corresponding one of said at least two fuses; and
a status-checking circuit operable to generate a status signal having (i) a first state when at least one of said at least two fuses is blown, and (ii) a second state otherwise.

2. The fuse-redundancy circuit for use in an integrated circuit as set forth in claim 1 wherein said at least two fuses are coupled in series.

3. The fuse-redundancy circuit for use in an integrated circuit as set forth in claim 1 wherein said at least two fuses are coupled in parallel.

4. The fuse-redundancy circuit for use in an integrated circuit as set forth in claim 1 wherein said status-checking circuit is one of an AND gate, a NAND gate, an OR gate and a NOR gate.

5. The fuse-redundancy circuit for use in an integrated circuit as set forth in claim 1 wherein each one of said at least two fuses has a first end and a second end, and wherein said first end of at least one of said at least two fuses is coupled to a first voltage reference.

6. The fuse-redundancy circuit for use in an integrated circuit as set forth in claim 5 wherein said second end of at least one of said at least two fuses is coupled to one of said first voltage reference and ground.

7. The fuse-redundancy circuit for use in an integrated circuit as set forth in claim 1 wherein one of said at least two fuse-control devices comprises on e of n-channel transistor, a p-channel transistor and a resistor.

8. The fuse-redundancy circuit for use in an integrated circuit as set forth in claim 1 wherein said at least two fuse-control devices control said electric current flowing through said corresponding fuses in response to a corresponding one of a plurality of fuse control signals.

9. For use in an integrated circuit (IC), a method of blowing a fuse-redundancy circuit having at least two fuses and at least two fuse-control devices, each one of said at least two fuse-control devices operable to control an electric current flowing through a corresponding one of said at least two fuses, said method comprising the steps of:
controlling current flowing through fuse-redundancy circuit, said current having a magnitude sufficient to blow each of said at least two fuses; and
generating a status signal having a first state when at least one of said at least two fuses is blown, and a second state otherwise.

10. The method of blowing a fuse-redundancy circuit as set forth in claim 9 wherein said at least two fuses are coupled in series.

11. The method of blowing a fuse-redundancy circuit as set forth in claim 9 wherein said at least two fuses are coupled in parallel.

12. The method of blowing a fuse-redundancy circuit as set forth in claim 9 wherein said generating step includes generating said status signal as an output of one of an AND gate, a NAND gate, an OR gate and a NOR gate.

13. The method of blowing a fuse-redundancy circuit as set forth in claim 9 wherein each one of said at least two fuses has a first end and a second end, and wherein said first end of at least one of said at least two fuses is coupled to a first voltage reference.

14. The method of blowing a fuse-redundancy circuit as set forth in claim 13 wherein said second end of at least one of said at least two fuses is coupled to one of said first voltage reference and ground.

15. The method of blowing a fuse-redundancy circuit as set forth in claim 9 wherein one of said at least two fuse-control devices comprises one of n-channel transistor, a p-channel transistor and a resistor.

16. The method of blowing a fuse-redundancy circuit as set forth in claim 9 wherein said at least two fuse-control devices control said electric current flowing through said corresponding fuses in response to a corresponding one of a plurality of fuse control signals.

17. For use in an integrated circuit (IC), a fuse-redundancy circuit comprising:
a first fuse and a second fuse;
a first fuse-control device operable to control a first current flowing through said first fuse;
a second fuse-control device operable to control a second current flowing through said second fuse; and
a status-checking circuit operable to generate a status signal having a first state when at least one of said first fuse and said second fuse is blown, and a second state otherwise.

18. The fuse-redundancy circuit for use in an integrated circuit as set forth in claim 17 wherein said at least two fuses are coupled in series.

19. The fuse-redundancy circuit for use in an integrated circuit as set forth in claim 17 wherein said at least two fuses are coupled in parallel.

20. The fuse-redundancy circuit for use in an integrated circuit as set forth in claim 17 wherein at least one of said first current and said second current flows respectively through said first fuse and said second fuse in response to a corresponding one of a plurality of fuse control signals.
